(19) United States
(12) Patent Application Publication
(10) Pub. No.: US 2009/0300448 A1
(43) Pub. Date: Dec. 3, 2009

(54) SCAN FLIP-FLOP DEVICE

(75) Inventors: Yoshihiro Tomita, Tokyo (JP); Yukinori Uchino, Kanagawa-ken (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/466,600

(22) Filed: May 15, 2009

(30) Foreign Application Priority Data
May 29, 2008 (JP) 2008-140610

(51) Int. Cl. G01R 31/3177; G06F 11/25

(52) U.S. Cl. 714/731; 714/733; 714/E11.155

(57) ABSTRACT

A scan flip-flop device has a scan flip-flop, a Nch insulated gate field effect transistor and a Pch insulated gate field effect transistor. The Nch insulated gate field effect transistor is located on an output side the scan flip-flop. The Nch insulated gate field effect transistor turns off and dose not output a signal when a test enable signal is in a disable mode. The Pch insulated gate field effect transistor is located between a higher voltage source and an output side of the Nch insulated gate field effect transistor. The Pch insulated gate field effect transistor turns on when a test enable signal is in a disable mode. The Pch insulated gate field effect transistor sets a SO port at a high level voltage.

### CROSS REFERENCE TO RELATED APPLICATION

This application is based upon and claims the benefit of priority from the prior Japanese Patent Application No. P2008-140610, filed on May 29, 2008, the entire contents of which are incorporated herein by reference.

### FIELD OF THE INVENTION

The invention relates to a scan flip-flop device.

### DESCRIPTION OF THE BACKGROUND

With recent progress of high performance and multifunction of information equipment and the like, a system LSI having a number of system functions integrated on one chip, a System on a Chip (SoC) having a memory, a logical circuit, and an analog circuit mounted on one chip, and the like have been often used for portable information devices, personal computers, etc. Large-scale and high-speed system LSIs and SoCs are configured by use of a technique called the Design for Testability (DFT) such as the scan test method and the Built in Self Test (BIST) method in order to reduce test costs and the like. In the scan test method, flip-flops are replaced with scan flip-flops. Use of the scan flip flops allows values to be set from the outside, and the values to be read through an external input output terminal. Japanese Patent Application Publication No. 2004-37264 discloses a scan flip-flop.

In the scan flip-flop, a demultiplexer method is used in which either of two pieces of data inputted into a multiplexer is selected on the basis of a test enable signal. A flip-flop formed of a master latch circuit, a slave latch circuit and the like is provided at an output side of the multiplexer. The master latch circuit and the slave latch circuit catch and hold the selected data on the basis of a system clock signal, and output the held data.

When the scan flip-flop employing the demultiplexer method receives an input of normal data and performs normal operation, an output signal is outputted also from a scan output terminal and then is inputted into a circuit at a rear stage (scan flip-flop, logical circuit, etc.), thereby causing a circuit of a test system that configures a scan chain to operate. For this reason, the test system also operates during a time other than the time of testing. Consequently, there is a problem of an increase in power consumption of semiconductor integrated circuits such as logic LSIs, system LSIs, or SoCs that have the scan flip-flop built-in.

### SUMMARY OF THE INVENTION

According to an aspect of the invention is provided a scan flip-flop device having first and second output terminals, comprising a scan flip-flop receiving a system clock signal, a normal data input signal, a test enable signal and a scan data input signal, the scan flip-flop outputting a normal data output signal to the first output terminal based on the system clock signal when the test enable signal is in a disable mode, the scan flip-flop further outputting a scan data output signal based on the system clock signal when the test enable signal is in a enable mode, a signal shutting down unit located on an output side of the scan flip-flop, the signal shutting down unit outputting the scan data output signal to the second output terminal when the test enable signal is in the enable mode, the signal shutting down unit shutting down so as not to output the scan data output signal to the second output terminal when the test enable signal is in the disable mode, and a voltage setting unit located between a higher voltage source and an output side of the signal shutting down unit, the voltage setting unit setting an output side of the signal shutting down unit at a fixed voltage when the test enable signal is in the disable mode, the voltage setting unit further outputting the fixed voltage to the second output terminal.

According to another aspect of the invention is provided a scan flip-flop device having first and second output terminals, comprising a scan flip-flop having a multiplexer, a master latch circuit, a slave latch circuit and a inverter, the multiplexer receiving a normal data input signal, a test enable signal and a scan data input signal, the multiplexer selecting and outputting the normal data input signal or the scan data input signal based on the system clock signal, the master latch circuit receiving an output signal of the multiplexer, the master latch circuit catching and holding a selected data in the multiplexer based on the system clock signal, the master latch circuit further outputting a held data, the slave latch circuit receiving an output signal of the master latch circuit, the slave latch circuit catching and holding a selected data in the master latch circuit based on the system clock signal, the slave latch circuit further outputting a held data, the inverter receiving an output signal of the slave latch circuit, the inverter outputting a reversed output signal of the slave latch circuit to the first output terminal, a Nch insulated gate field effect transistor located between the inverter and an output side of the second output terminal, the Nch insulated gate field effect transistor having a gate to be input the test enable signal, and a Pch insulated gate field effect transistor located between a higher voltage source and an output side of the Nch insulated gate field effect transistor, the Pch insulated gate field effect transistor having a gate to be input the test enable signal.

According to another aspect of the invention is provided a scan flip-flop device having first and second output terminals, comprising a scan flip-flop having a multiplexer, a master latch circuit, a slave latch circuit and a inverter, the multiplexer receiving a normal data input signal, a test enable signal and a scan data input signal, the multiplexer selecting and outputting the normal data input signal or the scan data input signal based on the system clock signal, the master latch circuit receiving an output signal of the multiplexer, the master latch circuit catching and holding a selected data in the multiplexer based on the system clock signal, the master latch circuit further outputting a held data, the slave latch circuit receiving an output signal of the master latch circuit, the slave latch circuit catching and holding a selected data in the master latch circuit based on the system clock signal, the slave latch circuit further outputting a held data, the inverter receiving an output signal of the slave latch circuit, the inverter outputting a reversed output signal of the slave latch circuit to the first output terminal, a transfer gate located between the inverter and an output side of the second output terminal, the transfer gate having a Nch insulated gate field effect transistor and a first Pch insulated gate field effect transistor, the Nch insulated gate field effect transistor having a gate to be input the test enable signal, the first Pch insulated gate field effect transistor having a gate to be input a reverse signal of the test enable signal, and a second Pch insulated gate field effect transistor located between a higher voltage source and an output side of the Nch insulated gate field effect transistor, the second Pch insulated gate field effect transistor having a gate to be input the test enable signal.

### BRIEF DESCRIPTION OF THE DRAWINGS

FIG. 1 is a circuit diagram showing a semiconductor integrated circuit according to a first embodiment of the invention.

FIG. 2 is a circuit diagram showing a scan flip-flop device according to the first embodiment of the invention.

FIG. 3 is a timing chart showing operations of the scan flip-flop device according to the first embodiment of the invention.

FIG. 4 is a timing chart showing operations of a scan flip-flop device according to a second embodiment of the invention.

FIG. 5 is a circuit diagram showing a semiconductor integrated circuit according to a third embodiment of the invention.

FIG. 6 is a circuit diagram showing a scan flip-flop device according to the third embodiment of the invention.

### DETAILED DESCRIPTION OF THE INVENTION

Embodiments of the invention will be described with reference to the drawings.

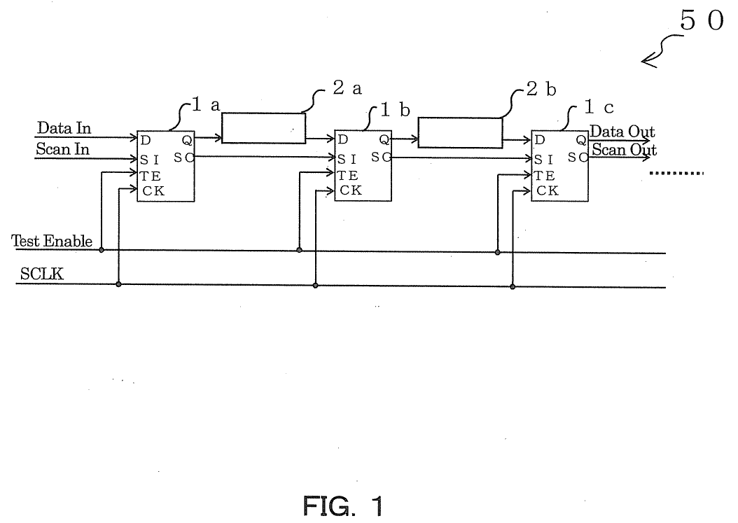

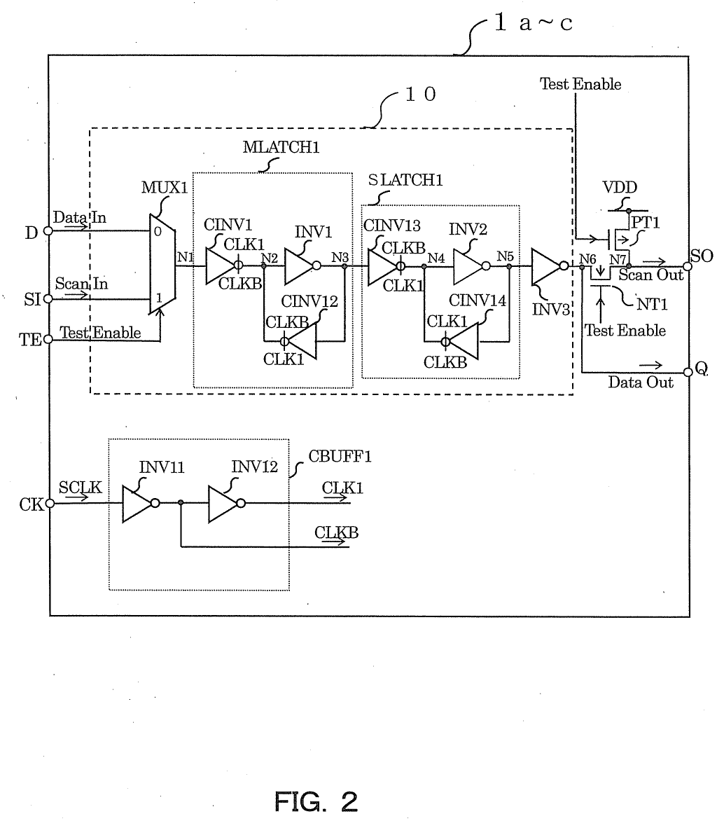

A scan flip-flop device according to a first embodiment of the invention will be described with reference to the drawings. FIG. 1 is a circuit diagram showing a semiconductor integrated circuit, and FIG. 2 is a circuit diagram showing a scan flip-flop device. In this embodiment, when a test enable signal is in a disable mode, a scan data output signal outputted from the scan flip-flop is set to a fixed voltage.

As shown in FIG. 1, scan flip-flop devices 1a, 1b, 1c, logic circuit portions 2a, 2b are provided in a semiconductor integrated circuit 50.

The semiconductor integrated circuit 50 has logical circuits not shown, such as a sequential circuit and a combinational circuit, in addition to the scan flip-flop devices 1a, 1b, 1c and the logic circuit portions 2a, 2b. The logical circuits form a scan chain. At the time of a test mode (also referred to as a scanning mode), a scan data input signal (Scan In) is inputted into the first scan flip-flop device 1a, and a scan data output signal (Scan Out) is finally outputted from an n-th scan flip-flop device not shown.

Here, the logical circuit has a sequential circuit and a combinational circuit. The sequential circuit includes flip-flops (F/F), latches, counters, shift registers, sequencers. The combinational circuit includes logic gates such as inverters (INV), OR circuits, AND circuits, NOR circuits, and XOR circuits, as well as selectors, multiplexers, adders.

At the time of normal operation (also referred to as a normal mode), the semiconductor integrated circuit 50 receives a normal data input signal called Primary Input or the like, and outputs a normal data output signal called Primary Output or the like. The semiconductor integrated circuit 50 is a logic LSI. The semiconductor integrated circuit 50 may be a system LSI or an SoC, in some cases.

The first scan flip-flop device 1a has a D port into which a normal data input signal (Data In) is inputted, has an SI port into which a scan data input signal (Scan In) is inputted, has a TE port into which a test enable signal is inputted, and has a CK port into which a system clock signal (SCLK) is inputted.

Moreover, the first can flip-flop device 2a has a Q port being a first output terminal from which a normal data output signal (Data Out) is outputted, and has an SO port being a second output terminal from which a scan data output signal (Scan Out) is outputted.

When the test enable signal is in an enable mode, the first scan flip-flop device 1a catches and holds a selected scan data input signal (Scan In) on the basis of a system clock signal (SCLK). Then, the first scan flip-flop device 1a outputs the held scan data input signal from the SO port, and the signal is inputted into an SI port of the second scan flip-flop device 1b. When the test enable signal is in a disable mode, the first scan flip-flop device 1a catches and holds a selected normal data input signal (Data In) on the basis of the system clock signal (SCLK), and outputs the held normal data input signal from the Q port.

Note that, the second and third scan flip-flop devices 1b, 1c and scan flip-flop devices after the third scan flip-flop device that are not shown have the same configuration and perform the same operation as that of the first scan flip-flop device 1a. Thus, a description of the configurations and operations of the second and third scan flip-flop devices, 1b, 1c and the scan flip-flop devices after the third scan flip-flop device 1c will be omitted.

The logic circuit portion 2a is provided between the Q port of the first scan flip-flop device 1a and the D port of the second scan flip-flop device 1b. The logic circuit portion 2b is provided between the Q port of the second scan flip-flop device 1b and the D port of the third scan flip-flop device 1c. In addition, other logic circuit portions not shown are each provided between a Q port of a scan flip-flop device disposed at a front stage of the corresponding logic circuit portion and a D port of a can flip-flop device disposed at a rear stage of the corresponding logic circuit portion.

As shown in FIG. 2, a scan flip-flop 10, an Nch insulated gate field effect transistor NT1, and a Pch insulated gate field effect transistor PT1 are provided in each of the scan flip-flop devices 1a, 1b, 1c. A multiplexer MUX1, a master latch circuit MLATCH1, a slave latch circuit SLATCH1, and an inverter INV3 are provided in the scan flip-flop 10.

The normal data input signal (Data In), the scan data input signal (Scan In), and the test enable signal are inputted into the multiplexer MUX1. Then, the multiplexer MUX1 selects the normal data input signal (Data In) or the scan data input signal (Scan In) on the basis of the test enable signal, and outputs the selected signal from a node N1. The scan data input signal (Scan In) is selected when the test enable signal is in the enable mode, and the normal data input signal (Data In) is selected when the test enable signal is in the disable mode.

Inverters INV11, INV12 are connected in series to a clock buffer CLKB. The inverter INV11 receives a system clock signal (SCLK), and inverts the signal to output the inverted signal to the master latch circuit MLATCH1 and the slave latch circuit SLATCH1 as a clock signal CLKB. The inverter INV12 receives the clock signal CLKB outputted from the inverter INV11, and inverts the signal to output the inverted signal to the master latch circuit MLATCH1 and the slave latch circuit SLATCH1 as a clock signal CLK1 (signal of the same phase as that of the system clock signal SCLK).

The master latch circuit MLATCH1 is provided between the multiplexer MUX1 and the slave latch circuit SLATCH1. Clocked inverters CINV11, CINV12, and an inverter INV1 are provided in the master latch circuit MLATCH1.

The clocked inverter CINV11 is provided between the node N1 and a node N2. The inverter INV1 and the clocked inverter CINV12 are provided between the node N2 and a node N3. An output side of the inverter INV1 is connected to an input side of the clocked inverter CINV12, and an output side of the clocked inverter CINV12 is connected to an input side of the inverter INV1.

The master latch circuit MLATCH1 catches the data selected by the multiplexer MUX1 during a “Low” level period of the system clock signal (SCLK), and holds the data thus caught during a “High” level period of the system clock signal (SCLK).

The slave latch circuit SLATCH1 is provided between the mask latch circuit MLATCH1 and the inverter INV3. Clocked inverters CINV13, CINV14, and an inverter INV2 are provided in the slave latch circuit SLATCH1.

The clocked inverter CINV13 is provided between the node N3 and a node N4. The inverter INV2 and the clocked inverter CINV14 are provided between the node N4 and a node N5. An output side of the inverter INV2 is connected to an input side of the clocked inverter CINV14, and an output side of the clocked inverter CINV14 is connected to an input side of the inverter INV2.

The slave latch circuit SLATCH1 catches an output signal of the master latch circuit MLATCH1 during the “High” level period of the system clock signal (SCLK), and holds the data thus caught during the “Low” level period.

The inverter INV3 is provided between the slave latch circuit SLATCH1 and the Nch insulated gate field effect transistor NT1 (between the node N5 and a node N6). The inverter INV3 receives a signal outputted from the slave latch circuit SLATCH1, and inverts the signal to output the normal data output signal (Data Out) to the Q port.

The Nch insulated gate field effect transistor NT1 is provided between the inverter INV3 and a drain of the Pch insulated gate field effect transistor PT1 (between the node N6 and a node N7), and has a gate into which the test enable signal is inputted.

The Nch insulated gate field effect transistor NT1 is turned on so as to output a signal of the node N6 when the test enable signal is in the enable mode (“High” level), and is turned off so as not to output the signal of the node N6 when the test enable signal is in the disable mode (“Low” level). Immediately after the test enable signal changes to the disable mode, an output side (node N7) of the Nch insulated gate field effect transistor NT1 becomes a high impedance state (HiZ).

The Pch insulated gate field effect transistor PT1 has a source connected to a higher voltage source VDD, has a drain connected to the node N7, and has a gate into which the test enable signal is inputted.

The Pch insulated gate field effect transistor PT1 is turned off to output the signal of the node N6 to the SO port when the test enable signal is in the enable mode (“High” level), and is turned on to forcibly set the node N7 to a fixed voltage (“High” level) and output the voltage to the SO port when the test enable signal is in the disable mode (“Low” level). Here, to forcibly set means setting the node N7 to a voltage of the “High” level irrespective of a state of the output side of the Nch insulated gate field effect transistor NT1 (HiZ state, etc.).

The Nch insulated gate field effect transistor NT1 functions as a signal shutting down unit that shuts down the scan data output signal. The Pch insulated gate field effect transistor PT1 functions as a voltage setting unit that sets the output side of the Nch insulated gate field effect transistor NT1 to a fixed voltage. The insulated gate field effect transistor includes MOSFETs and MISFETs. Here, the MOSFETs are used for the Nch insulated gate field effect transistor NT1, the Pch insulated gate field effect transistor PT1, and a transistor that configures the circuit.

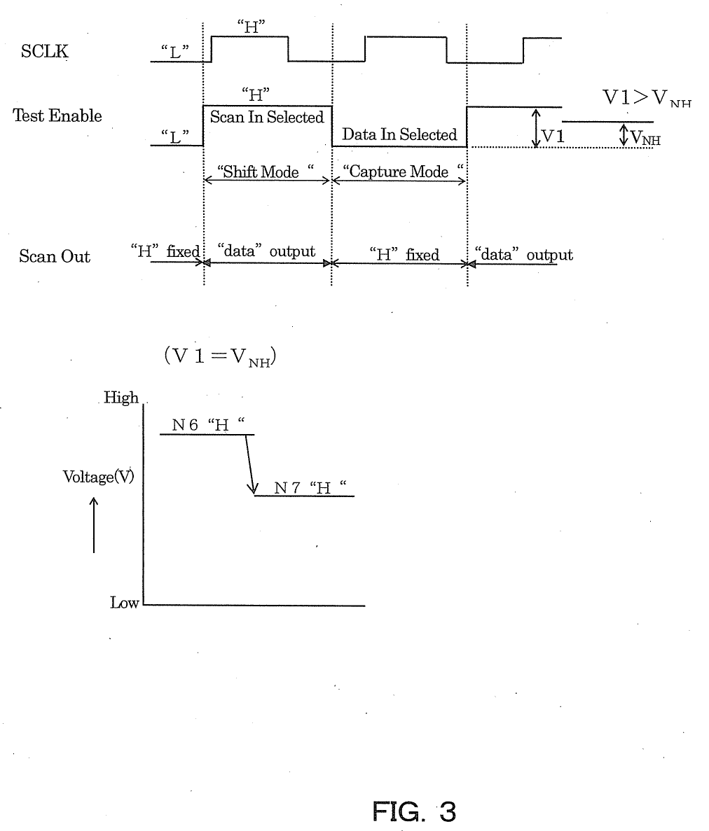

Next, a description will be given of operations of the scan flip-flop device with reference to FIG. 3. FIG. 3 is a timing chart showing the operations of the scan flip-flop device.

As shown in FIG. 3, in each of the scan flip-flop devices 1a, 1b, 1c, when the test enable signal is in the enable mode (“High” level), the scan data input signal (Scan In) is selected. The scan data input signal (Scan In) is caught and held at a rising edge of the system clock signal (SCLK). The held scan data input signal is then outputted from the SO port (“shift mode”). At this time, a signal is also outputted from the Q port.

Meanwhile, when the test enable signal is in the disable mode (“Low” level), the normal data input signal (Data In) is selected. The normal data input signal (Data In) is caught and held at a rising edge of the system clock signal (SCLK). The held data signal is then outputted from the Q port (“capture mode”). At this time, the output of the SO port is set to the “High” level of a fixed voltage by the Nch insulated gate field effect transistor NT1 that is the signal shutting down unit and the Pch insulated gate field effect transistor PT1 that is the voltage setting unit. In other words, the Nch insulated gate field effect transistor NT1 and the Pch insulated gate field effect transistor PT1 dynamically shut down the scan data output signal (Scan Out).

If a relationship between a “High” level voltage V1 of the test enable signal and a “High” voltage V_{NH} of a node (any one of the N1, N2, N3, N4, N5, N6) within the scan flip-flop device is set as

V1=V_{NH} formula (1),

the “High” level at the output side (node N7) reduces (by approximately an absolute value of a threshold voltage of the Nch insulated gate field effect transistor NT1) when the Nch insulated gate field effect transistor NT1 is turned on.

In this embodiment, the relationship between the “High” level voltage V1 of the test enable signal and the “High” voltage V_{NH} of the node (any one of the N1, N2, N3, N4, N5, N6) within the scan flip-flop device is set as

V1>V_{NH} formula (2).

For this reason, it is possible to suppress reduction in the “High” level at the output side (node N7) that occurs when the Nch insulated gate field effect transistor NT1 is turned on.

As mentioned above, the scan flip-flop device of this embodiment is provided with the scan flip-flop 10, the Nch insulated gate field effect transistor NT1, and the Pch insulated gate field effect transistor PT1. The Nch insulated gate field effect transistor NT1 is provided at the output side of the scan flip-flop 10, and has the gate into which the test enable signal is inputted. When the test enable signal is in the disable mode, the Nch insulated gate field effect transistor NT1 is turned off so as not to output the output signal. The Pch insulated gate field effect transistor PT1 is provided between the higher voltage source VDD and the output side of the Nch insulated gate field effect transistor NT1. When the test enable signal is in the disable mode, the Pch insulated gate field effect transistor PT1 is turned on to set the SO port to the “High” level. The “High” level voltage V1 of the test enable signal is set higher than the “High” level voltage V_{NH} of each of the nodes N1, N2, N3, N4, N5, N6 within the flip-flop 10.

For this reason, when the normal data is inputted into one of the scan flip-flop devices 1a, 1b, 1c and the normal operation is performed, the SO port is fixed at the voltage of the “High” level without the output signal outputted from the SO port. Therefore, a test system circuit that configures the scan chain does not operate, thus enabling a reduction in power consumption of the semiconductor integrated circuit 50. In addition, when the scan data input signal (Scan In) is inputted into one of the can flip-flop devices 1a, 1b, 1c and the scan operation is performed, the “High” level voltage of the scan data output signal (Scan Out) outputted from the SO port can be stabilized.

Note that, while a MOSFET is used for the Nch insulated gate field effect transistor NT1, the Pch insulated gate field effect transistor PT1, and the transistor that configures the circuit in this embodiment, a MISFET may be used alternatively. Moreover, a Q/port (third output terminal) that outputs an inverted signal of the normal data output signal (Data Out) may be added to the output side of each of the scan flip-flop devices 1a, 1b, 1c.

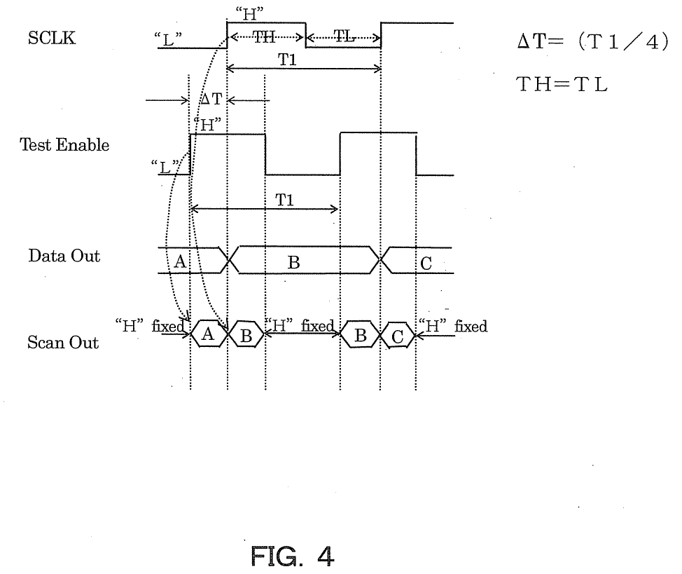

A scan flip-flop device according to a second embodiment of the invention will be described with reference to the drawings. FIG. 4 is a timing chart showing operations of the scan flip-flop device. In this embodiment, the system clock signal and the test enable signal are set in the same cycle time. Here, the scan flip-flop device has the same configuration as that of the first embodiment.

As shown in FIG. 4, the system clock signal (SCLK) and the test enable signal are set in the same cycle time (one cycle time T1), and a rising edge of the system clock signal (SCLK) is delayed more than a rising edge of the test enable signal. A delay time (phase difference ΔT between the signals) is set within a range of

0<ΔT<(T1/2) formula (3).

Here, ΔT is set to (T1/4). The system clock signal (SCLK) and the test enable signal are set to have the same “High” level period TH and the same “Low” level period TL (duty 50%, 50%).

Since such a setting prevents generation of the rising edge of the system clock signal (SCLK) when the test enable signal is in the disable mode (Low), the normal data input signal (Data In) inputted from the D port is not taken into each of the scan flip-flop devices 1a, 1b, 1c. Accordingly, only the scan data input signal (Scan In) inputted into the SI port is held at the rising edge of the system clock signal (SCLK), and the held data is outputted.

The data outputted as the normal data output signal (Data Out) from the Q port of each of the scan flip-flop devices 1a, 1b, 1c is updated, i.e., data A, data B, data C, and . . . are outputted in turn, at each rising edge of the system clock signal (SCLK).

On the other hand, the scan data output signal (Scan Out) outputted from the SO port of each of the scan flip-flop devices 1a, 1b, 1c is fixed at the “High” level when the test enable signal is in the disable mode (Low), and the data outputted as the scan data output signal is updated at each rising edge of the system clock signal (SCLK).

Accordingly, with the scan flip-flop devices 1a, 1b, 1c according to this embodiment, it is possible to treat the system clock signal (SCLK) and the test enable signal as a double-layer clock pulse. This consequently allows the scan flip-flop devices 1a, 1b, 1c of this embodiment to perform a shift register operation with a stabilized output level of the scan data output signal (Scan Out).

As mentioned above, in the scan flip-flop device of this embodiment, the system clock signal (SCLK) and the test enable signal are set in the same cycle time (one cycle time T1), and the rising edge of the system clock signal (SCLK) is delayed more than the rising edge of the test enable signal. Moreover, the delay time (phase difference ΔT between the signals) is set in the range of 0<ΔT<(T1/2).

Since this prevents generation of the rising edge of the system clock signal (SCLK) when the test enable signal is in the disable mode, the normal data input signal (Data In) inputted into the D port is not taken into each of the scan flip-flop devices 1a, 1b, 1c. Accordingly, only the scan data input signal (Scan In) inputted into the SI port is held at the rising edge of the system clock signal (SCLK), and the held data is outputted.

Therefore, each of the scan flip-flop devices 1a, 1b, 1c can be made as a shift register that operates on the basis of a double-layer clock pulse formed of the system clock signal (SCLK) and the test enable signal.

Note that, the “High” level period TH and the “Low” level period TL of the test enable signal are set to be the same in this embodiment. Alternatively, the “Low” level period TL may be shortened, the “High” level period may be increased, and a period of the shift register operation may be increased.

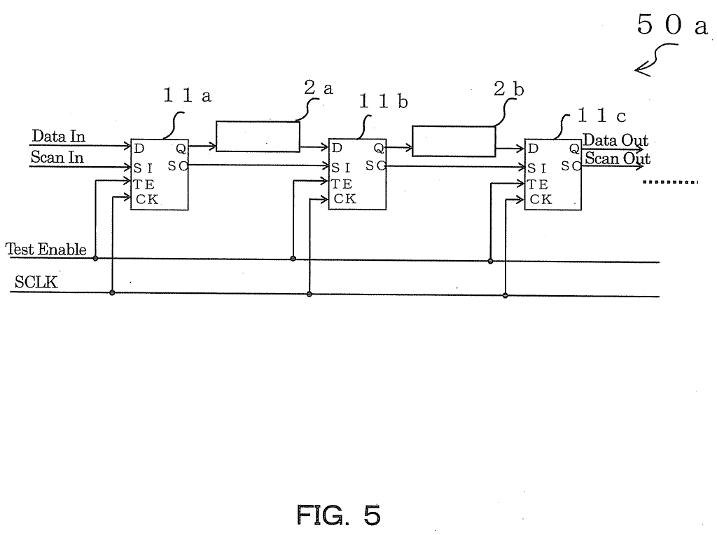

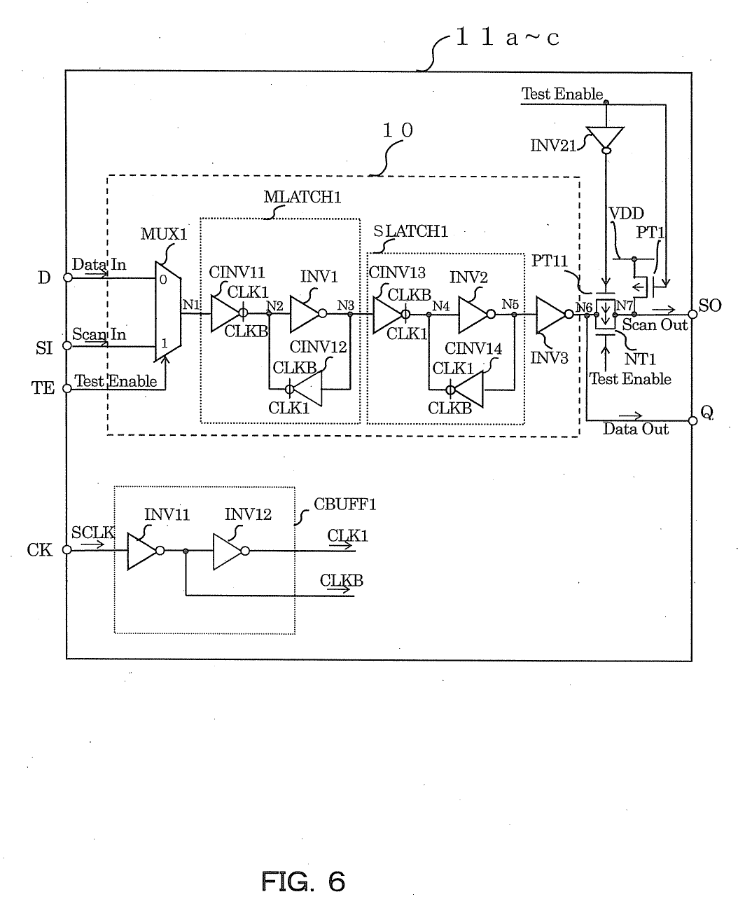

A description will be given of a scan flip-flop device according to a third embodiment of the invention with reference to the drawings. FIG. 5 is a circuit diagram showing a semiconductor integrated circuit, and FIG. 6 is a circuit diagram showing a scan flip-flop device. The configuration of the signal shutting down unit is changed in this embodiment.

Hereinafter, the same reference numerals will be given to the same configuration portions as those in the first embodiment. A description of the same configuration portions will be omitted and only different portions will be described.

As shown in FIG. 5, scan flip-flop devices 11a, 11b, 11c, logic circuit portions 2a, 2b are provided in a semiconductor integrated circuit 50a.

The semiconductor integrated circuit 50a has logical circuits not shown, such as a sequential circuit and a combinational circuit, in addition to the scan flip-flop devices 11a, 11b, 11c, the logic circuit portions 2a, 2b. The logical circuits form a scan chain. At the time of a test mode (also referred to as a scanning mode), a scan data input signal (Scan In) is inputted into the first scan flip-flop device 11a, and a scan data output signal (Scan Out) is finally outputted from an n-th scan flip-flop device not shown.

The first scan flip-flop device 11a has a D port into which a normal data input signal (Data In) is inputted, has an SI port into which a scan data input signal (Scan In) is inputted, has a TE port into which a test enable signal is inputted, and has a CK port into which a system clock signal (SCLK) is inputted.

The first scan-flip-flop device 11a has a Q port being a first output terminal from which a normal data output signal (Data Out) is outputted, and has an SO port being a second output terminal from which a scan data output signal (Scan Out) is outputted.

When the test enable signal is in the enable mode, the first scan flip-flop device 11a catches and holds a selected scan data input signal (Scan In) on the basis of the system clock signal (SCLK). Then, the first scan flip-flop device 11a outputs the held signal from the SO port, and the signal is inputted into an SI port of a second scan flip-flop device 11b. When the test enable signal is in the disable mode, the first scan flip-flop device 11a catches and holds a selected normal data input signal (Data In) on the basis of the system clock signal (SCLK), and outputs the held signal from the Q port.

Note that, the second and third scan flip-flop devices 11b, 11c, and scan flip-flop devices after the third scan flip-flop device, which are not shown, have the same configuration and perform the same operation as that of the first scan flip-flop device 11a. Thus, a description of the configurations and operations of the second and third scan flip-flop devices 11b, 11c, and the scan flip-flop devices after the third scan flip-flop device 11c will be omitted.

As shown in FIG. 6, each of the scan flip-flop devices 11a, 11b, 11c is provided with a scan flip-flop 10, an Nch insulated gate field effect transistor NT1, a Pch insulated gate field effect transistor PT1, and a Pch insulated gate field effect transistor PT11.

The Pch insulated gate field effect transistor PT11 is provided between an inverter INV3 and a drain of the Pch insulated gate field effect transistor PT1 (between a node N6 and a node N7), and has a gate into which a signal inverted from the test enable signal by an inverter INV21 is inputted.

The Nch insulated gate field effect transistor NT1 and the Pch insulated gate field effect transistor PT11 configure a transfer gate. The Nch insulated gate field effect transistor NT1 and the Pch insulated gate field effect transistor PT11 function as a signal shutting down unit.

The transfer gate formed of the Nch insulated gate field effect transistor NT1 and the Pch insulated gate field effect transistor PT11 can suppress a drop in a voltage of the “High” level at the output side, in comparison with a case where only the Nch insulated gate field effect transistor NT1 is used as in the first embodiment.

As mentioned above, the scan flip-flop device of this embodiment is provided with the scan flip-flop 10, the Nch insulated gate field effect transistor NT1, the Pch insulated gate field effect transistor PT1, and the Pch insulated gate field effect transistor PT11. The Nch insulated gate field effect transistor NT1 and the Pch insulated gate field effect transistor PT11 are provided at the output side of the scan flip-flop 10, and configure the transfer gate. When the test enable signal is in the disable mode, the Nch insulated gate field effect transistor NT1 and the Pch insulated gate field effect transistor PT11 are turned off so as not to output the output signal. The Pch insulated gate field effect transistor PT1 is provided between a higher voltage source VDD and the output side of the transfer gate. When the test enable signal is in the disable mode, the Pch insulated gate field effect transistor PT1 is turned on to set the SO port to the “High” level.

For this reason, when the normal data is inputted into each of the scan flip-flop devices 11a, 11b, 11c and the normal operation is performed, the SO port is fixed at a voltage of the “High” level without the output signal outputted from the SO port. Therefore, a test system circuit that configures the scan chain does not operate, thus enabling a reduction in power consumption of the semiconductor integrated circuit 50a.

The invention will not be limited to the above-mentioned embodiments, and various modifications of the invention can be made without departing from the gist of the invention.

For example, while the Nch insulated gate field effect transistor is used for the signal shutting down unit in the first embodiment, a Pch insulated gate field effect transistor may be used alternatively. In that case, preferably, an inverted signal of the test enable signal is inputted into the gate of the Pch insulated gate field effect transistor. Moreover, while the Pch insulated gate field effect transistor is used for the voltage setting unit in the first embodiment, an Nch insulated gate field effect transistor may be used alternatively. In that case, preferably, an inverted signal of the test enable signal is inputted into the gate of the Nch insulated gate field effect transistor.

What is claimed is:

1. A scan flip-flop device having first and second output terminals, comprising:
a scan flip-flop receiving a system clock signal, a normal data input signal, a test enable signal and a scan data input signal, the scan flip-flop outputting a normal data output signal to the first output terminal based on the system clock signal when the test enable signal is in a disable mode, the scan flip-flop further outputting a scan data output signal based on the system clock signal when the test enable signal is in a enable mode;
a signal shutting down unit located on an output side of the scan flip-flop, the signal shutting down unit outputting the scan data output signal to the second output terminal when the test enable signal is in the enable mode, the signal shutting down unit shutting down so as not to output the scan data output signal to the second output terminal when the test enable signal is in the disable mode; and
a voltage setting unit located between a higher voltage source and an output side of the signal shutting down unit, the voltage setting unit setting an output side of the signal shutting down unit at a fixed voltage when the test enable signal is in the disable mode, the voltage setting unit further outputting the fixed voltage to the second output terminal.

2. The scan flip-flop device according to claim 1, wherein a high level voltage of the test enable signal is set higher than a high level voltage of a inner node of the scan flip-flop so as to stabilize a high level voltage of the scan data output signal to be output from the signal shutting down unit.

3. The scan flip-flop device according to claim 1, wherein the system clock signal and the test enable signal are setting in a same cycle time, and wherein a rising edge of the system clock signal is delayed more than a rising edge of the test enable signal, and wherein a delay time is setting more than zero and less than a half of the cycle time.

4. The scan flip-flop device according to claim 1, wherein the scan flip-flop has a third output terminal to be input a reverse signal of the normal data output signal.

5. The scan flip-flop device according to claim 1, wherein the signal shutting down unit is a Nch insulated gate field effect transistor having a gate to be input the test enable signal.

6. The scan flip-flop device according to claim 1, wherein the signal shutting down unit is a Pch insulated gate field effect transistor having a gate to be input a reverse signal of the test enable signal.

7. The scan flip-flop device according to claim 1, wherein the signal shutting down unit is a transfer gate having a Nch and a Pch insulated gate field effect transistors, the Nch insulated gate field effect transistor has a gate to be input the test enable signal, the Pch insulated gate field effect transistor has a gate to be input a reverse signal of the test enable signal.

8. The scan flip-flop device according to claim 1, wherein the voltage setting unit is a Pch insulated gate field effect transistor having a gate to be input the test enable signal.

9. The scan flip-flop device according to claim 1, wherein the voltage setting unit is a Nch insulated gate field effect transistor having a gate to be input a reverse signal of the test enable signal.

10. A scan flip-flop device having first and second output terminals, comprising:
a scan flip-flop having a multiplexer, a master latch circuit, a slave latch circuit and a inverter, the multiplexer receiving a normal data input signal, a test enable signal and a scan data input signal, the multiplexer selecting and outputting the normal data input signal or the scan data input signal based on the system clock signal, the master latch circuit receiving an output signal of the multiplexer, the master latch circuit catching and holding a selected data in the multiplexer based on the system clock signal, the master latch circuit further outputting a held data, the slave latch circuit receiving an output signal of the master latch circuit, the slave latch circuit catching and holding a selected data in the master latch circuit based on the system clock signal, the slave latch circuit further outputting a held data, the inverter receiving an output signal of the slave latch circuit, the inverter outputting a reversed output signal of the slave latch circuit to the first output terminal;
a Nch insulated gate field effect transistor located between the inverter and an output side of the second output terminal, the Nch insulated gate field effect transistor having a gate to be input the test enable signal; and
a Pch insulated gate field effect transistor located between a higher voltage source and an output side of the Nch insulated gate field effect transistor, the Pch insulated gate field effect transistor having a gate to be input the test enable signal.

11. The scan flip-flop device according to claim 10, wherein the scan flip-flop has a third output terminal to be input a reverse output signal of the inverter

12. A scan flip-flop device having first and second output terminals, comprising:
a scan flip-flop having a multiplexer, a master latch circuit, a slave latch circuit and a inverter, the multiplexer receiving a normal data input signal, a test enable signal and a scan data input signal, the multiplexer selecting and outputting the normal data input signal or the scan data input signal based on the system clock signal, the master latch circuit receiving an output signal of the multiplexer, the master latch circuit catching and holding a selected data in the multiplexer based on the system clock signal, the master latch circuit further outputting a held data, the slave latch circuit receiving an output signal of the master latch circuit, the slave latch circuit catching and holding a selected data in the master latch circuit based on the system clock signal, the slave latch circuit further outputting a held data, the inverter receiving an output signal of the slave latch circuit, the inverter outputting a reversed output signal of the slave latch circuit to the first output terminal;
a transfer gate located between the inverter and an output side of the second output terminal, the transfer gate having a Nch insulated gate field effect transistor and a first Pch insulated gate field effect transistor, the Nch insulated gate field effect transistor having a gate to be input the test enable signal, the first Pch insulated gate field effect transistor having a gate to be input a reverse signal of the test enable signal; and
a second Pch insulated gate field effect transistor located between a higher voltage source and an output side of the Nch insulated gate field effect transistor, the second Pch insulated gate field effect transistor having a gate to be input the test enable signal.

13. The scan flip-flop device according to claim 12, wherein the scan flip-flop has a third output terminal to be input a reverse output signal of the inverter.
